(19) United States
(12) Patent Application Publication
(10) Pub. No.: US 2014/0222376 A1
(43) Pub. Date: Aug. 7, 2014

(54) METHOD FOR SEARCHING, ANALYZING, AND OPTIMIZING PROCESS PARAMETERS AND COMPUTER PROGRAM PRODUCT THEREOF

(71) Applicants: FORESIGHT TECHNOLOGY COMPANY, LTD., TAINAN CITY (TW); NATIONAL CHENG KUNG UNIVERSITY, TAINAN CITY (TW)

(72) Inventors: Chi-An KAO, TAINAN CITY (TW); Chih-Hsuan CHENG, Miaoli County (TW); Wei-Ming WU, TAINAN CITY (TW); Fan-Tien CHENG, TAINAN (TW)

(73) Assignees: NATIONAL CHENG KUNG UNIVERSITY, TAINAN CITY (TW); FORESIGHT TECHNOLOGY COMPANY, LTD., TAINAN CITY (TW)

(21) Appl. No.: 13/846,951

(22) Filed: Mar. 19, 2013

(30) Foreign Application Priority Data
Feb. 7, 2013 (TW) 102104846

(51) Int. Cl. H01L 21/66

(52) U.S. Cl. CPC H01L 22/10
USPC 702/182

(57) ABSTRACT

A method for searching, analyzing, and optimizing process parameters and a computer product thereof are provided. At first, sets of process data that are generated when a process tool processes workpieces are obtained respectively, each set of process data including process parameters. Then, sets of metrology data measured by a metrology tool are obtained, wherein the sets of metrology data are corresponding to the sets of the process data in a one-to-one manner, each workpiece having at least one measurement point, each set of metrology data including at least one actual measurement value of at least one measurement item at the at least one measurement point. Thereafter, critical parameters are selected from the process parameters. Then, values of the critical parameters are adjusted to enable predicted measurement values of the measurement points of one workpiece to meet a quality target value.

### RELATED APPLICATIONS

The present application is based on, and claims priority from Taiwan Application Serial Number 102104846, filed Feb. 7, 2013, the disclosure of which is hereby incorporated by reference herein in its entirety.

### BACKGROUND

1. Field of Invention

The present invention relates to a method for searching, analyzing, and optimizing process parameters and a computer program product thereof. More particularly, the present invention relates to a method for searching, analyzing, and optimizing process parameters with parameter optimization and a computer program product thereof.

2. Description of Related Art

During the manufacturing of semiconductor, TFT-LCD or other products, a manufacturing system will collect a plurality of sets of process data which are automatically generated or manually recorded when a plurality of workpieces are processed by a process tool, and actual measurement values at measurement points of the workpieces, for product monitoring or failure analysis. However, the process data contain a tremendous number of process parameters, includes such as the prior-process historical data, the current process step H/W and process data, as well as the product context data. When an event occurs and the process tool needs adjustment (tool adjustment), engineer often fails to find out the event causes from such a huge amount of parameters data rapidly and effectively for determining what process parameters are important and need adjustment.

A conventional skill adopts design of experiment to determine key process parameters. The design of experiment technique is a design using replication and randomization to offset the influences of the factors (known or unknown) other than specific factors, so as to purify and observe the effects resulted from the influence of the specific factors, thus promoting the accuracy of analysis results. The main purpose of the design of experiment is to test the relationships between dependent variables and independent variables listed in an experimental hypothesis. However, since the amount of the process parameter is huge, it takes a lot of test measurement samples and test time to perform the design of experiment. In addition, different process tools possess different process parameters. For a plant with many process tools, it requires an astonishing amount of test measurement samples and test time to determine what process parameters are important and need adjustment in all of the process tools.

Further, one workpiece generally has plural measurement points, and different combinations of process parameters have different impacts on the respective measurement points. If the conventional skill (design of experiment) is used to find out different parameter combinations for individually adjusting the respective measurement point (for example, adjusting the uniformity of wafer thickness), it becomes a very difficult assignment.

Hence, there is a need to provide a method for searching, analyzing, and optimizing process parameters and a computer program product thereof to overcome the disadvantages of the aforementioned conventional skills.

### SUMMARY

An object of the present invention is to provide a method for searching, analyzing, and optimizing process parameters and a computer program product thereof for effectively selecting key parameters affecting production quality from process parameters, thereby saving the amount of test measurement samples (such as workpieces, wafers or glass substrates) and test time consumed by the design of experiment.

Another object of the present invention is to provide a method for searching, analyzing, and optimizing process parameters and a computer program product thereof for performing parameter optimization on each measurement point of the workpieces, thereby obtaining good workpiece quality.

According to an aspect of the present invention, a method for searching, analyzing, and optimizing process parameters is provided. In this method, at first, a plurality of sets of process data which are generated when a process tool processes a plurality of workpieces respectively are obtained, wherein each of the sets of process data includes a plurality of process parameters, and the sets of process data are respectively corresponding to the workpieces in a one-to-one manner. Then, a plurality of sets of metrology data measured by a metrology tool are obtained, wherein the sets of metrology data are corresponding to the sets of the process data in a one-to-one manner, wherein each of the workpieces has at least one measurement point, and each of the sets of metrology data includes at least one actual measurement value of at least one measurement item at the at least one measurement point. Thereafter, a parameter-selecting step is performed for selecting a plurality of key parameters from the process parameters. Then, a parameter-optimization step is performed for adjusting the values of the key parameters to make predicted measurement values at the measurement points of one workpiece meet a quality target value.

In the parameter-selecting step, at first, a step is performed for choosing if a clustering scheme is activated, thereby obtaining a first result. When the first result is yes, the clustering scheme is performed, wherein the clustering scheme includes a grouping step and a representative-parameter searching step. In the grouping step, at first, a first correlation analysis is performed with respect to each of the sets of process data on each of the process parameters and the remaining process parameters therein, thereby obtaining a plurality of first correlation coefficients between each of the process parameters and the remaining process parameters in each of the sets of process data. Thereafter, a step is performed for grouping the process parameters of which the absolute values of the first correlation coefficients are greater or equal to a correlation coefficient threshold (for example, 0.7) as one group, thereby obtaining a plurality of first groups. Then, an intersection-and-union operation is performed on the process parameters in the first groups, thereby obtaining a plurality of second groups, wherein in the intersection-and-union operation, an union operation is performed on every two of the first groups which intersect each other. Thereafter, a representative-parameter searching step is performed. In the representative-parameter searching step, a second correlation analysis is performed with respect to each of the second groups on each of the process parameters therein and the actual measurement values at the measurement points of the workpieces, thereby obtaining a plurality of second correlation coefficients between each of the process parameters and the actual measurement values at the measurement points of the workpieces. Then, a step is performed for selecting the process parameter in each of the second groups with the largest second correlation coefficient as representative, thereby obtaining a plurality of representative parameters. Thereafter, a step to is performed for determining if the number of the workpieces is smaller than n times of the number of the representative parameters, wherein n is greater than 1 (for example, 2.5), thereby obtaining a second result. When the second result is yes, a parameter-reduction step is performed for selecting a plurality of key parameters from the representative parameters. When the second result is no, all of the representative parameters are considered as a plurality of key parameters. Then, a step is performed for simplifying the sets of process data as a plurality of sets of critical process data, wherein each of the sets of critical process data consisting of a plurality of key parameters.

In the parameter-optimization step, the sets of critical process data and their corresponding sets of metrology data are used to build a predictive model in accordance with an algorithm, such as a partial least squares (PLS), a regression-based partial least squares (PLS), a multi-regression (MR) algorithm, a nonlinear regression algorithm, or a logic regression algorithm. Then, steps are performed for selecting at least one adjusting parameter from the key parameters; determining a parameter count of the adjusting parameters desired to be adjusted; and setting an adjustment amount of each of the adjusting parameters desired to be adjusted. Thereafter, an adjustment step is performed for conjecturing at least one predicted measurement value of the at least one measurement point by inputting values of one set of critical process data to the predictive model and setting at least one value of the at least one adjusting parameter in accordance the parameter count and the adjustment amount. Then, a step is performed for determining if the at least one predicted measurement value of the at least one measurement point enters an allowable range of a quality target value, thereby obtaining a determination result. When the determination result is no, the adjustment step is repeated.

In one embodiment, the aforementioned method for searching, analyzing, and optimizing process parameters further includes a data-preprocessing step. The data-preprocessing step includes: deleting the process parameters in the sets of process data of which the standard deviations are smaller than a first threshold value (for example, 0.0001); deleting the process parameters in the first half (50%) of sets of process data of which the standard deviations are smaller than the first threshold value; deleting the process parameters in the second half of sets of process data of which the standard deviations are smaller than the first threshold value; deleting the process parameters in the sets of process data of which the coefficients of variation are smaller than a second threshold value (for example, 0.001); or deleting the process parameters in the sets of process data of which the correlation coefficients with the actual measurement values at the measurement points of the workpieces are smaller than a third threshold value (for example, 0.01).

In one embodiment, in the parameter-reduction step, a stepwise selection step is repetitively performed on the representative parameters until the input and output numbers of the representative parameters to the stepwise selection step are the same, thereby obtaining a plurality of selected parameters. Then, a step is performed for determining if the number of the workpieces is smaller than n times of the number of the selected parameters, wherein n is greater than 1, thereby obtaining a third result. When the third result is yes, steps are performed for sorting the selected parameters in descending order by their second correlation coefficients, and selecting the first M number of sorted and selected parameters as the key parameters, wherein M is the number of the workpieces divided by n. When the third result is no, a step is performed for selecting the selected parameters as the key parameters.

In another embodiment, in the parameter-reduction step, steps are performed for sorting the process parameters in descending order by their second correlation coefficients, and selecting the first M number of sorted process parameters as a plurality of key parameters, wherein M is the number of the workpieces divided by n.

According to another aspect of the present invention, a computer program product stored on a non-transitory tangible computer readable recording medium is provided. When this computer program product is loaded and executed by a computer, the aforementioned method for searching, analyzing, and optimizing process parameters is performed.

Hence, the application of the embodiments of the present invention can effectively select key parameters affecting production quality from a huge amount of process parameters, thereby saving the amount of test measurement samples and test time consumed by the design of experiment; and can perform parameter optimization on each measurement point of the workpieces, thereby obtaining good workpiece quality.

### BRIEF DESCRIPTION OF THE DRAWINGS

These and other features, aspects, and advantages of the present invention will become better understood with regard to the following description, appended claims, and accompanying drawings where:

FIG. 1 is a flow chart showing a method for searching, analyzing, and optimizing process parameters according to an embodiment of the present invention;

FIG. 2A to FIG. 2C are flow charts showing a parameter-selecting step according to an embodiment of the present invention;

FIG. 3 is a flow chart showing a grouping step according to an embodiment of the present invention;

FIG. 4 is a flow chart showing a parameter-optimization step according to an embodiment of the present invention; and

FIG. 5 illustrates the results of applying the method for searching, analyzing, and optimizing process parameters according to the embodiment of the present invention.

### DESCRIPTION OF THE PREFERRED EMBODIMENTS

Reference will now be made in detail to the embodiments of the present invention, examples of which are illustrated in the accompanying drawings. Wherever possible, the same reference numbers are used in the drawings and the description to refer to the same or like parts.

Embodiments of the present invention link workpiece quality (the measurement values such as thickness, brightness, sheet resistance, etc.) to production process information (the process parameters such as temperature, pressure, deposition time, etc.) for analyzing and learning the degrees of influence of the important process parameters on the product quality (measurement values) by using a multivariate theory, thereby finding the optimum production conditions (process parameters) currently to improve product yield and gross margin.

Embodiments of the present invention mainly use correlation analysis of statistics to a correlation coefficient between every two process parameters and correlation coefficients between process parameters and metrology data, wherein the correlation coefficients are between 0 and 1. When the absolute value of a correlation coefficient between two process parameters is larger, it represents that the collinearity between the process parameters is higher, such that the process parameters have high homogeneity and can be grouped as one group. When the absolute value of a correlation coefficient between a process parameter and metrology data is larger, it represents that the process parameter has greater prediction capability on the metrology data. When the correlation coefficient between two process parameters is equal to 0 or smaller than a certain threshold, it represents that the two process parameters are uncorrelated, each of which should be classified as one group independently. As to the algorithm of correlation coefficient, it is well known to those skilled in the art, and thus not described in detail herein.

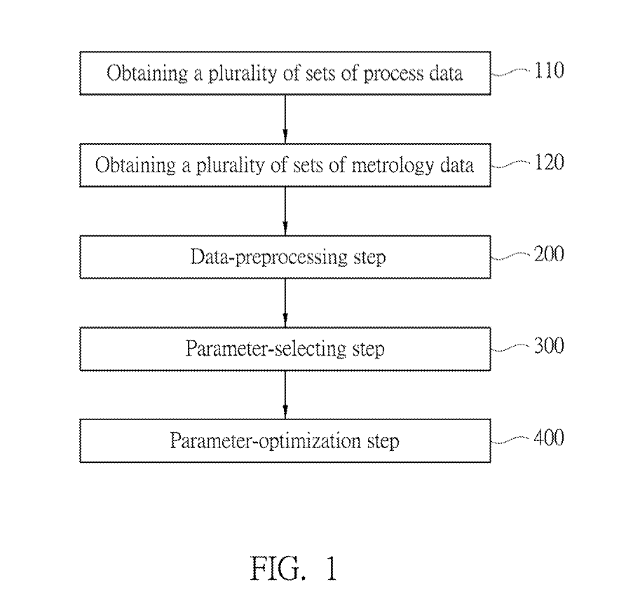

Referring to FIG. 1, FIG. 1 is a flow chart showing a method for searching, analyzing, and optimizing process parameters according to an embodiment of the present invention. At first, step 110 is for obtaining a plurality of sets of process data Xⱼ which are generated when a process tool processes a plurality of workpieces (such as wafers or glass substrates) respectively, wherein each of the sets of process data Xⱼ includes a plurality of process parameters xᵢ, wherein i is used for indicating the i^{th} process parameter, and j is used for indicating the j^{th} workpiece, and the sets of process data (Xⱼ) are respectively corresponding to the workpieces (j) in a one-to-one manner. Then, step 120 is performed for obtaining a plurality of sets of metrology data (yⱼ) measured by a metrology tool obtained, wherein the sets of metrology data (yᵢ) are corresponding to the sets of the process data (Xⱼ) in a one-to-one manner. Each of the workpieces has at least one measurement point, and each of the sets of metrology data (yⱼ) includes at least one actual measurement value of at least one measurement item at the at least one measurement point. For example, there are 36 measurement points on a wafer, and each measurement point has at least one measurement item (such as thickness, electrical properties, physical properties, etc.). Thereafter, a data-preprocessing step 200 is performed. The data-preprocessing step 200 includes: deleting the process parameters in the sets of process data of which the standard deviations are smaller than a first threshold value (for example, 0.0001); deleting the process parameters in the first half of sets of process data of which the standard deviations are smaller than the first threshold value; deleting the process parameters in the second half of sets of process data of which the standard deviations are smaller than the first threshold value; deleting the process parameters in the sets of process data of which the coefficients of variation are smaller than a second threshold value (for example, 0.001); or deleting the process parameters in the sets of process data of which the correlation coefficients with the actual measurement values at the measurement points of the workpieces are smaller than a third threshold value (for example, 0.01). It is worthy to be noted that a user may adjust the aforementioned first, second and third threshold values in accordance with actual conditions. Further, the data-preprocessing step 200 also may delete the process parameters in the process data of which the mission rates are higher than, for example, 3%; and/or delete the sets of process data in which the value of any parameter is null or overflow (for example, 999999999.999). The purpose of the data-preprocessing step 200 is filter out of invalid or uninfluential process data or process parameters. For example, when the standard deviation of one certain process parameter in the sets of process data is too small, it represents that the values of the process parameter corresponding to different actual measurement values has little fluctuation and cannot be used for predicting the measurement values at the measurement points of a workpiece. When the correlation coefficient between one certain process parameter and the actual measurements at the measurement points is too small, it represents that the process parameter has quite small affect on the actual measurement values.

Thereafter, a parameter-selecting step 300 is performed for selecting a plurality of key parameters from the process parameters, so as to simplify the sets of process data as a plurality of sets of critical process data, wherein each of the sets of critical process data consisting of a plurality of key parameters. Then, a parameter-optimization step 400 is performed for adjusting the values of the key parameters to make predicted measurement values at the measurement points of one workpiece meet a quality target value, thereby finding the optimum values of the process parameters.

Hereinafter, the parameter-selecting step 300 and the parameter-optimization step 400 are described respectively.

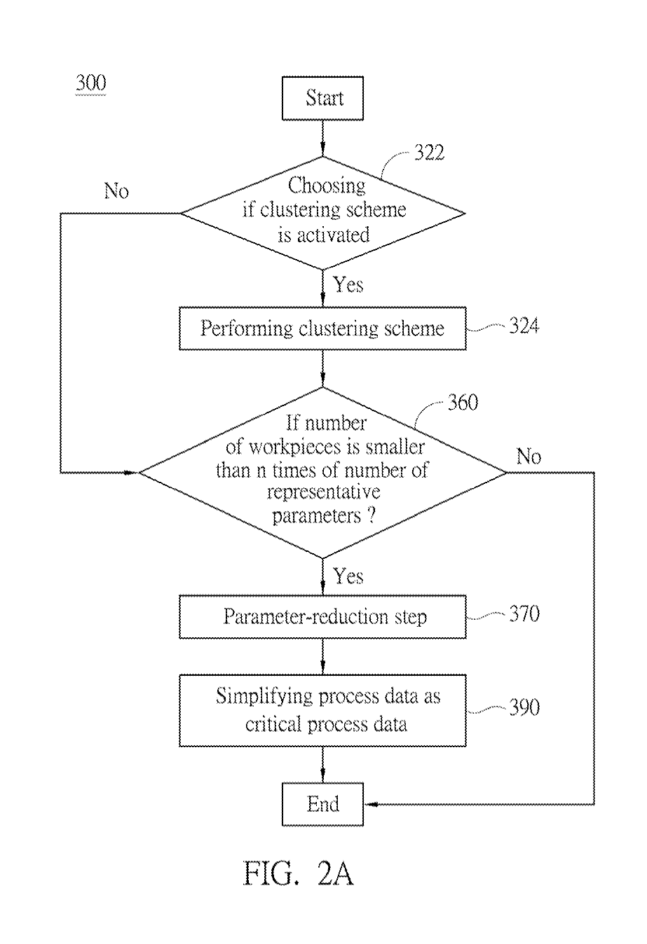

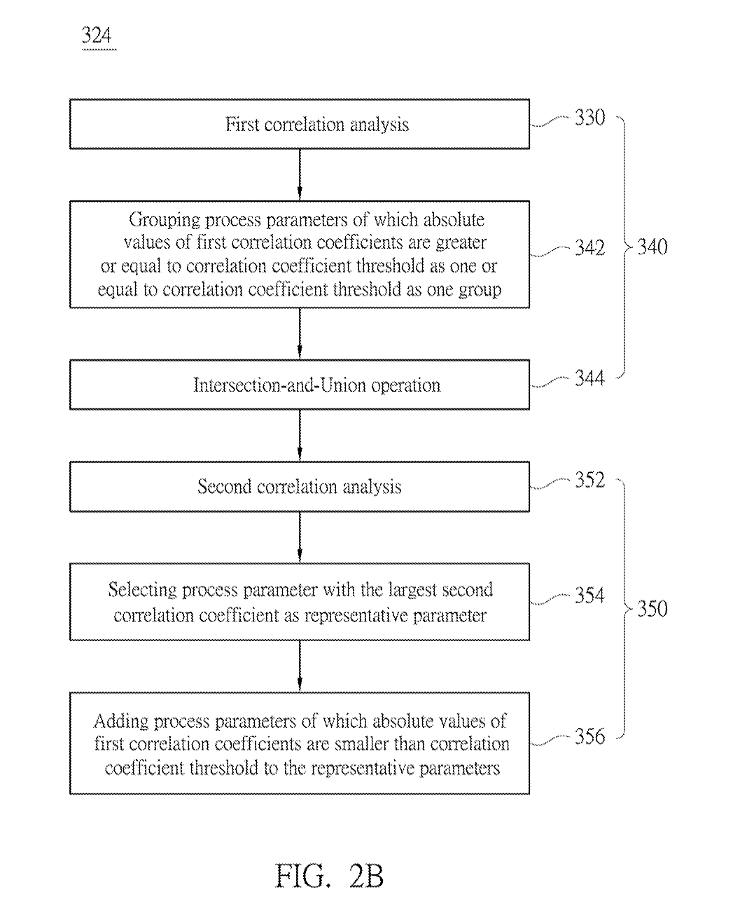

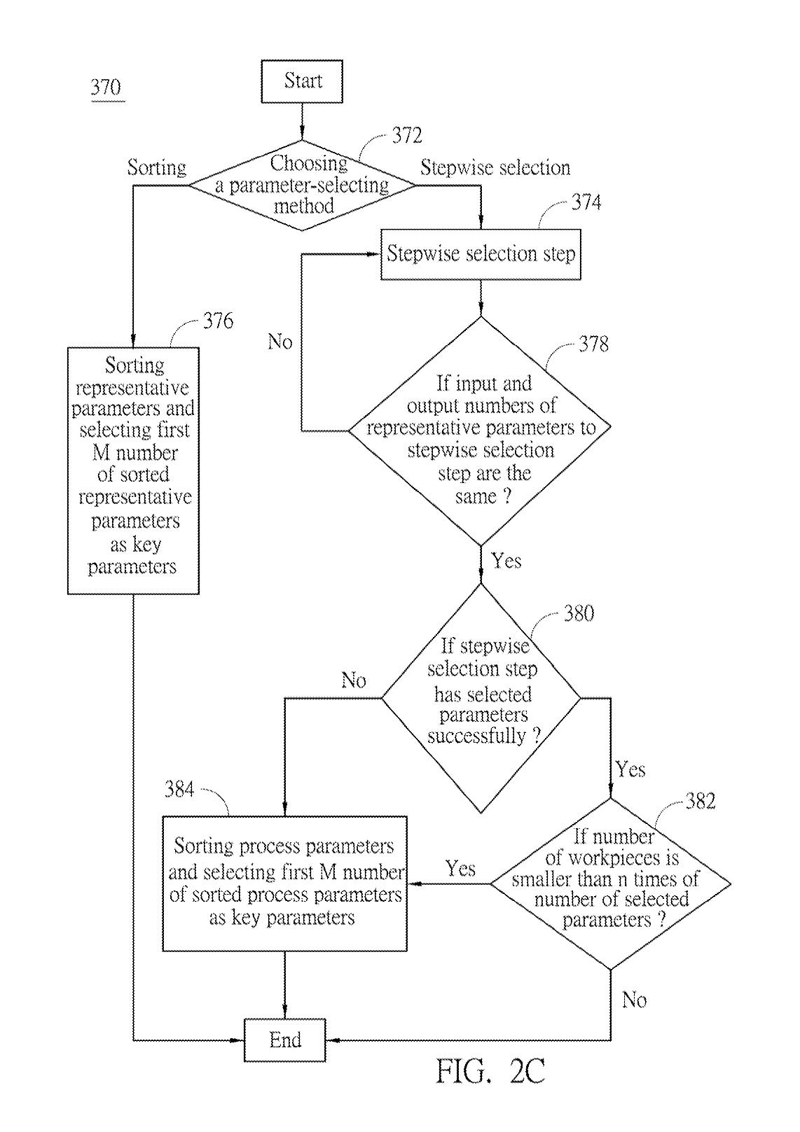

Referring to FIG. 2A to FIG. 2C, FIG. 2A to FIG. 2C are flow charts showing a parameter-selecting step 300 according to an embodiment of the present invention. As shown in FIG. 2A, at first, step 322 is performed for choosing if a clustering scheme 324 is activated, thereby obtaining a first result. When the first result is yes, the clustering scheme 324 is performed for selecting a plurality of representative parameters from the process parameters. When the first result is no, all of the process parameters are considered as the representative parameters. The so-called “representative parameters” are the ones of the process parameters which have greater influence than the others thereof on production quality. Then, step 360 is performed for determining if the number of the workpieces is smaller than n times of the number of the representative parameters, wherein n is greater than 1 (for example, 2.5), thereby obtaining a second result. When the second result is yes, a parameter-reduction step 370 is performed for selecting a plurality of key parameters from the representative parameters. When the second result is no, all of the representative parameters are considered as a plurality of key parameters. In other words, when the number of the workpieces is smaller than n times of the number of the representative parameters, the number of the workpieces is enough in comparison with the number of the representative parameters, such that all of the representative parameters are the key parameters greatly affecting production quality. Thereafter, step 390 is performed for simplifying the sets of process data as a plurality of sets of critical process data, wherein each of the sets of critical process data consisting of the key parameters.

Hereinafter, the clustering scheme 324 and the parameter-reduction step 370 are explained in detail.

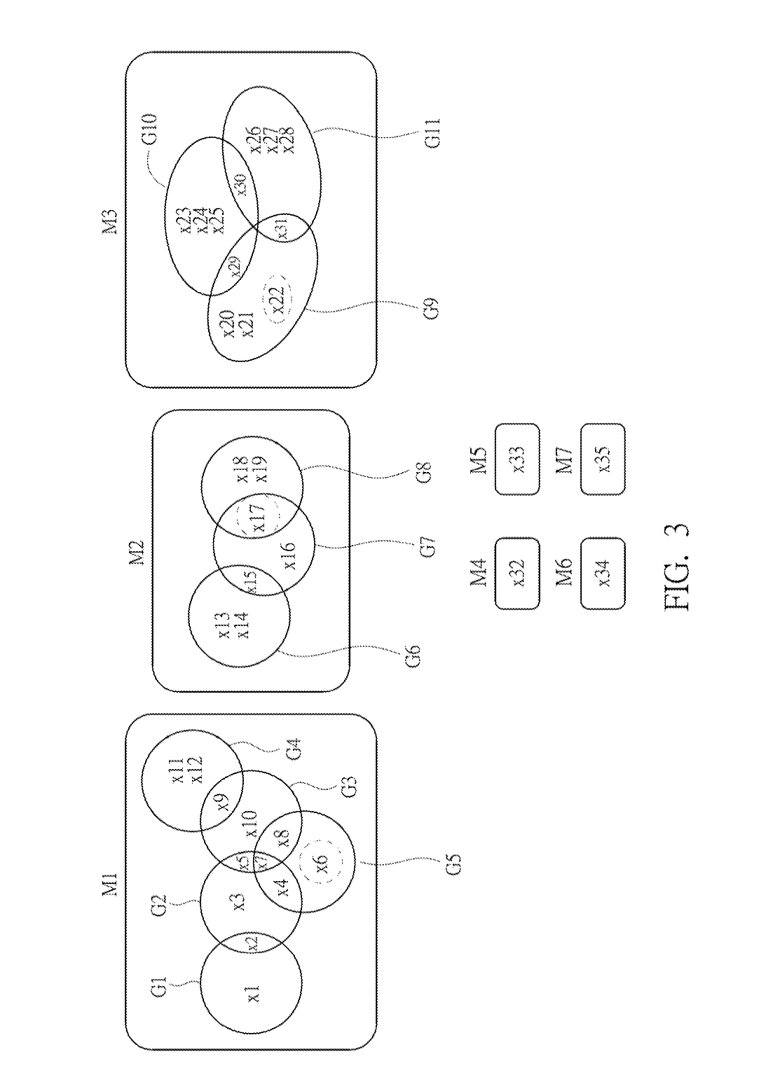

As shown in FIG. 2B, the clustering scheme includes a grouping step 340 and a representative-parameter searching step 350. In the grouping step 340, a first correlation analysis 330 is performed with respect each of the sets of process data on each of the process parameters and the remaining process parameters therein, thereby obtaining a plurality of first correlation coefficients between each of the process parameters and the remaining process parameters in each of the sets of process data. Thereafter, referring to FIG. 3, FIG. 3 is a flow chart showing a grouping step according to an embodiment of the present invention, wherein 35 process parameters x1-x35 are used for explanation. After the first correlation analysis 330 is completed, at first, with respect to each of the process parameters, step 342 is performed for grouping the process parameters of which the absolute values of the first correlation coefficients are greater or equal to a correlation coefficient threshold (for example, 0.7) as one group, thereby obtaining a plurality of first groups G1-G11. It is worthy to be noted that a user may adjust the aforementioned correlation coefficient threshold value in accordance with actual conditions. Then, an intersection-and-union operation 344 is performed on the process parameters in the first groups G1-G11, thereby obtaining a plurality of second groups M1, M2 and M3, wherein in the intersection-and-union operation 344, an union operation is performed on every two of the first groups G1-G11 which intersect each other.

Thereafter, a representative-parameter searching step 350 is performed. In the representative-parameter searching step 350, a second correlation analysis 352 is performed with respect to each of the second groups M1, M2 and M3 on each of the process parameters therein and the actual measurement values at the measurement points of the workpieces, thereby obtaining a plurality of second correlation coefficients between each of the process parameters in the second groups M1, M2 and M3 and the actual measurement values at the measurement points of the workpieces. Then, step 354 is performed for selecting the process parameter in each of the second groups with the largest second correlation coefficient as representative, thereby obtaining a plurality of representative parameters x6, x17 and x22. Thereafter, step 356 is performed for adding the process parameters x32, x33, x34 and x35 of which the absolute values of the first correlation coefficients are smaller than the correlation coefficient threshold to the representative parameters. In other words, the process parameters x32, x33, x34 and x35 are classified as independent groups M4, M5, M6 and M7, and become representative parameters.

In sum, the present embodiment selects the representative parameters x6, x17, x22, x32, x33, x34 and x35 from the process parameters x1-x35. In other words, the number of process parameters with representativeness can be greatly reduced to 7 from 35.

Thereafter, as shown in FIG. 2C, the parameter-reduction step 370 is performed for selecting a plurality of key parameters from the representative parameters. In the parameter-reduction step 370, at first, step 372 is performed for choosing a parameter-selecting method. When sorting is chosen as the parameter-selecting method, step 376 is performed for sorting the representative parameters in descending order by their second correlation coefficients, and selecting the first M number of sorted representative parameters as a plurality of key parameters, wherein M is the number of the workpieces divided by n. For example, let the total amount of the workpieces is 100, and 120 representative parameters remains after the process parameters with high collinearities are removed (if the clustering scheme is not activated, the representative parameters are the original process parameters.), the first 40 (M=40=100/2.5) ones of the 120 selected parameters which are highly correlated (the second correlation coefficients) with the metrology data will be selected as the key parameters.

When stepwise selection is chosen as the parameter-selecting method, a stepwise selection step 374 is repetitively performed on the representative parameters until the input and output numbers of the representative parameters to the stepwise selection step 374 are the same (step 378), thereby obtaining a plurality of selected parameters. In other words, the stepwise selection step 374 uses the output at the previous iteration as the input for the present iteration, and is repetitively performed until the number of the input parameters is the same as that of output parameters at the present iteration. As to the stepwise selection algorithm adopted by the stepwise selection step 374 is well known to those who are skilled in the art, and thus are not explained in detail herein.

Then, step 380 is performed for checking if the stepwise selection step 374 has selected parameters successfully. The step 380 is a precautionary step for confirming if unimportant parameters are removed by the stepwise selection step 374, and thus the step 380 can be skipped. When the stepwise selection step 374 fails to select any parameter, step 384 is performed for sorting the representative (process) parameters in descending order by their second correlation coefficients, and selecting the first M number of sorted representative (process) parameters as the key parameters, wherein M is the number of the workpieces divided by n. When the stepwise selection step 374 has selected parameters, step 382 is performed for determining if the number of the workpieces is smaller than n times of the number of the selected parameters, wherein n is greater than 1. If the result of step 382 is yes, the selected (process) parameters are sorted in descending order by their second correlation coefficients, and the first M number of sorted and selected (process) parameters are selected as the key parameters, wherein M is the number of the workpieces divided by n. If the result of the step 382 is no, the selected parameters are the key parameters.

The aforementioned “process parameters” are the original process parameters to be selected; the aforementioned “representative parameters” are the process parameters selected by the clustering scheme, which have a great influence on the production quality; the aforementioned “selected parameters” are the representative parameters selected by the stepwise selection step, which have a greater influence on the production quality; and the aforementioned “key parameters” are the ultimate process parameters selected by the embodiments of the present invention, which have the greatest influence on the production quality. As to the order of the respective steps described above, it may be adjusted by those who are skilled in the art in accordance with actual requirements, in which some of the steps may be performed simultaneously.

Hereinafter, the parameter-optimization step 400 is explained in detail. It is noted that the parameter-optimization step can perform optimization operation of process parameters not only with respect to one single measurement item but also to two or more measurement items at the same time.

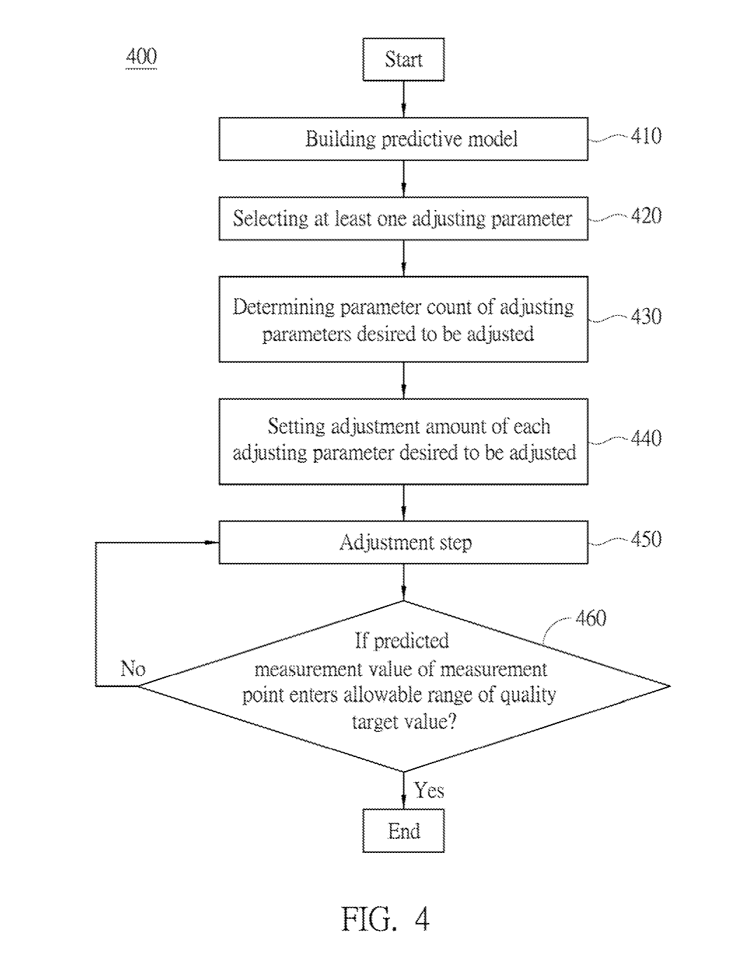

Referring to FIG. 4, FIG. 4 is a flow chart showing a parameter-optimization step 400 according to an embodiment of the present invention. In the parameter-optimization step 400, at first, the sets of critical process data and their corresponding sets of metrology data are used to build a predictive model in accordance with an algorithm (step 410), such as a partial least squares (PLS), a regression-based partial least squares (PLS), a multi-regression (MR) algorithm, a nonlinear regression algorithm, or a logic regression algorithm, etc. The PLS is a algorithm technique combining principle component analysis (PCA) with multiple regression (MR), which can overcome the collinearity problem derived between data, and take the relationship between the independent item (X) and the dependent variable (y). It is worthy to be noted that embodiments of the present invention may use the techniques of beta value, coefficient of correlation (R2) and lor F-test to determine the significance and sensitivities of key parameters, thereby forming an order of importance of the key parameters.

Then, step 420 is performed for selecting at least one adjusting parameter from the key parameters; step 430 is performed for determining a parameter count of the adjusting parameters desired to be adjusted; and step 440 is performed for setting an adjustment amount of each of the adjusting parameters desired to be adjusted. Thereafter, an adjustment step 450 is performed for conjecturing at least one predicted measurement value of the at least one measurement point by inputting values of one set of critical process data to the predictive model and setting at least one value of the at least one adjusting parameter in accordance the parameter count and the adjustment amount. Then, step 460 is performed for determining if the at least one predicted measurement value of the at least one measurement point enters an allowable range of a quality target value, thereby obtaining a determination result. When the determination result is no, the adjustment step 450 is repeated until the predicted measurement value of the measurement point reaches the allowable range of the quality target value.

TABLE 1

| Parameter No. | Parameter Name | Significance |
|---|---|---|
| 1 | Deposition time | yes |
| 7 | PM1_temperature-A | yes |
| 9 | PM1_temperature-C | yes |
| 8 | PM1_temperature-B | yes |
| 14 | PM3_temperature-B | yes |
| 12 | PM2_temperature-C | yes |
| 18 | PM4_temperature-C | yes |
| 15 | PM3_temperature-C | yes |
| 20 | Tool usage time | yes |
| 10 | PM2_temperature-A | yes |
| 6 | Gas-5-filter1 | no |
| 19 | Pressure filter 1 | no |

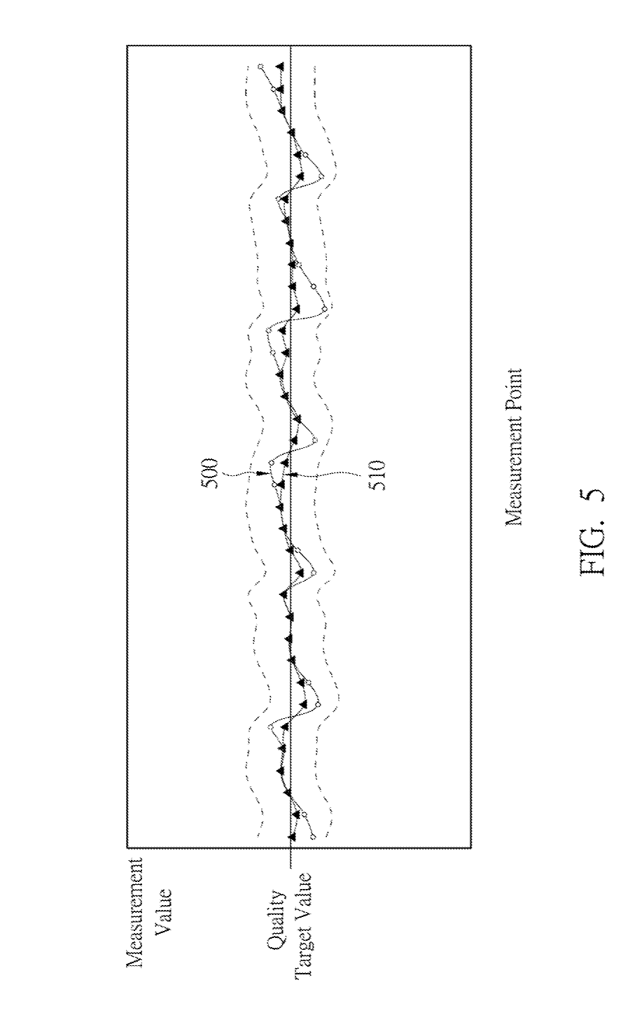

An application example is used for explanation, as shown in Table 1, wherein 10 adjusting parameters (of which significances are “yes”) are selected from 1000 key parameters, and it is determined that two of the adjusting parameters are desired to be adjusted each time; the adjustment amount of each of the adjusting parameters desired to be adjusted each time is ±5, which is performed for 11 times with the increment or decrement of one unit each time. Hence, there are C₂¹⁰=45 parameter combinations in the application example, and the total adjustment times of the parameters are C₂¹⁰×(11×11−1)=5400 times. Referring to FIG. 5, FIG. 5 illustrates the results of applying the method for searching, analyzing, and optimizing process parameters according to the embodiment of the present invention, wherein there are 36 measurement points on one workpiece. After 5400 times of adjustment, when parameter 1 (Deposition time) is adjusted from 144.072 to 131.856, and parameter 7 (PM1_temperature-A) is adjusted from 179.760 to 184.721, the actual measurement values (thickness) of the 36 measurement points can be adjusted to a post-adjustment curve 510 from a pre-adjustment curve 500. Hence, the embodiment of the present invention may find out the key parameters affecting the product quality and obtain the optimum values of the key parameters for obtaining excellent actual measurement values. As shown in FIG. 5, the post-adjustment curve 510 exhibits optimum uniformity.

The aforementioned embodiments can be provided as a computer program product, which may include a machine-readable medium on which instructions are stored for programming a computer (or other electronic devices) to perform a process based on the embodiments of the present invention. The machine-readable medium can be, but is not limited to, a floppy diskette, an optical disk, a compact disk-read-only memory (CD-ROM), a magneto-optical disk, a read-only memory (ROM), a random access memory (RAM), an erasable programmable read-only memory (EPROM), an electrically erasable programmable read-only memory (EEPROM), a magnetic or optical card, a flash memory, or another type of media/machine-readable medium suitable for storing electronic instructions. Moreover, the embodiments of the present invention also can be downloaded as a computer program product, which may be transferred from a remote computer to a requesting computer by using data signals via a communication link (such as a network connection or the like).

It can be known from the above that, with the application of the embodiments of the present invention, key parameters affecting production quality can be effectively selected from a huge amount of process parameters, thereby saving the amount of test measurement samples and test time consumed by the design of experiment, thus achieving a low-cost key parameters analysis; tool adjustment can be executed accurately; personnel learning curves can be shortened; and key parameters can be accurately monitored, thus promoting product quality.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method for searching, analyzing, and optimizing process parameters, comprising:
obtaining a plurality of sets of process data which are generated when a process tool processes a plurality of workpieces respectively, wherein each of the sets of process data includes a plurality of process parameters, and the sets of process data are respectively corresponding to the workpieces in a one-to-one manner;
obtaining a plurality of sets of metrology data measured by a metrology tool, wherein the sets of metrology data are corresponding to the sets of the process data in a one-to-one manner, wherein each of the workpieces has at least one measurement point, and each of the sets of metrology data comprises at least one actual measurement value of at least one measurement item at the at least one measurement point;
is performing a parameter-selecting step, the parameter-selecting step comprising:
choosing if a clustering scheme is activated, thereby obtaining a first result;
performing the clustering scheme when the first result is yes, the clustering scheme comprising:
performing a grouping step, the grouping step comprising:
performing a first correlation analysis with respect to each of the sets of process data on each of the process parameters and the remaining process parameters therein, thereby obtaining a plurality of first correlation coefficients between each of the process parameters and the remaining process parameters in each of the sets of process data;
grouping the process parameters of which the absolute values of the first correlation coefficients are greater or equal to a correlation coefficient threshold as one group, thereby obtaining a plurality of first groups; and
performing a intersection-and-union operation on the process parameters in the first groups, thereby obtaining a plurality of second groups, wherein in the intersection-and-union operation, an union operation is performed on every two of the first groups which intersect each other; and
performing a representative-parameter searching step, the representative-parameter searching step comprising:
performing a second correlation analysis with respect to each of the second groups on each of the process parameters therein and the actual measurement values at the measurement points of the workpieces, thereby obtaining a plurality of second correlation coefficients between each of the process parameters in the second groups and the actual measurement values at the measurement points of the workpieces; and
selecting the process parameter in each of the second groups with the largest second correlation coefficient as representative, thereby obtaining a plurality of representative parameters;
determining if the number of the workpieces is smaller than n times of the number of the representative parameters, wherein n is greater than 1, thereby obtaining a second result;
when the second result is yes, performing a parameter-reduction step for selecting a plurality of key parameters from the representative parameters; when the second result is no, considering all of the representative parameters as a plurality of key parameters; and
simplifying the sets of process data as a plurality of sets of critical process data, wherein each of the sets of critical process data consisting of a plurality of key parameters;
performing a parameter-optimization step, the parameter-optimization step comprising:
using the sets of critical process data and their corresponding sets of metrology data to build a predictive model in accordance with an algorithm;
selecting at least one adjusting parameter from the key parameters;
determining a parameter count of the adjusting parameters desired to be adjusted;
setting an adjustment amount of each of the adjusting parameters desired to be adjusted;
performing an adjustment step for conjecturing at least one predicted measurement value of the at least one measurement point by inputting values of one set of critical process data to the predictive model and setting at least one value of the at least one adjusting parameter in accordance the parameter count and the adjustment amount;
determining if the at least one predicted measurement value of the at least one measurement point enters an allowable range of a quality target value, thereby obtaining a determination result, wherein, when the determination result is no, the adjustment step is repeated.

2. The method as claimed in claim 1, further comprising:
to performing a data-preprocessing step, the data-preprocessing step comprising:
deleting the process parameters in the sets of process data of which the standard deviations are smaller than a first threshold value;
deleting the process parameters in the first half of sets of process data of which the standard deviations are smaller than the first threshold value;
deleting the process parameters in the second half of sets of process data of which the standard deviations are smaller than the first threshold value;
deleting the process parameters in the sets of process data of which the coefficients of variation are smaller than a second threshold value; or
deleting the process parameters in the sets of process data of which the correlation coefficients with the actual measurement values at the measurement points of the workpieces are smaller than a third threshold value.

3. The method as claimed in claim 1, wherein the first threshold value is 0.0001, the second threshold value is 0.001 and the third threshold value is 0.01.

4. The method as claimed in claim 1, wherein the algorithm is a partial least squares (PLS), a regression-based partial least squares (PLS), a multi-regression (MR) algorithm, a nonlinear regression algorithm, or a logic regression algorithm.

5. The method as claimed in claim 1, wherein the parameter-reduction step further comprises:
repetitively performing a stepwise selection step on the representative parameters until the input and output numbers of the representative parameters to the stepwise selection step are the same, thereby obtaining a plurality of selected parameters;
determining if the number of the workpieces is smaller than n times of the number of the selected parameters, wherein n is greater than 1, thereby obtaining a third result;
when the third result is yes, sorting the selected parameters in descending order by their second correlation coefficients, and selecting the first M number of sorted and selected parameters as the key parameters, wherein M is the number of the workpieces divided by n; and
when the third result is no, selecting the selected parameters as the key parameters.

6. The method as claimed in claim 5, wherein n is equal to 2.5.

7. The method as claimed in claim 1, wherein the parameter-reduction step further comprises:
when the first result is no, determining if the number of the workpieces is smaller than n times of the number of the process parameters, wherein n is greater than 1, thereby obtaining a second result;
when the second result is yes, sorting the process parameters in descending order by their second correlation coefficients, and selecting the first M number of sorted process parameters as a plurality of key parameters, wherein M is the number of the workpieces divided by n.

8. The method as claimed in claim 7, wherein n is equal to 2.5.

9. The method as claimed in claim 1, wherein the correlation coefficient threshold is equal to 0.7.

10. The method as claimed in claim 1, wherein the representative-parameter searching step further comprises:
adding the process parameters of which the absolute values of the first correlation coefficients are smaller than the correlation coefficient threshold to the representative parameters.

11. A computer program product stored on a non-transitory tangible computer readable recording medium, which, when executed, performs a method for searching, analyzing, and optimizing process parameters, the method comprising:
obtaining a plurality of sets of process data which are generated when a process tool processes a plurality of workpieces respectively, wherein each of the sets of process data includes a plurality of process parameters, and the sets of process data are respectively corresponding to the workpieces in a one-to-one manner;
obtaining a plurality of sets of metrology data measured by a metrology tool, wherein the sets of metrology data are corresponding to the sets of the process data in a one-to-one manner, wherein each of the workpieces has at least one measurement point, and each of the sets of metrology data comprises at least one actual measurement value of at least one measurement item at the at least one measurement point;
performing a parameter-selecting step, the parameter-selecting step comprising:
choosing if a clustering scheme is activated, thereby obtaining a first result;
performing the clustering scheme when the first result is yes, the clustering scheme comprising:
performing a grouping step, the grouping step comprising:
performing a first correlation analysis with respect to each of the sets of process data on each of the process parameters and the remaining process parameters therein, thereby obtaining a plurality of first correlation coefficients between each of the process parameters and the remaining process parameters in each of the sets of process data;
grouping the process parameters of which the absolute values of the first correlation coefficients are greater or equal to a correlation coefficient threshold as one group, thereby obtaining a plurality of first groups; and
performing a intersection-and-union operation on the process parameters in the first groups, thereby obtaining a plurality of second groups, wherein in the intersection-and-union operation, an union operation is performed on every two of the first groups which intersect each other; and
performing a representative-parameter searching step, the representative-parameter searching step comprising:
performing a second correlation analysis with respect to each of the second groups on each of the process parameters therein and the actual measurement values at the measurement points of the workpieces, thereby obtaining a plurality of second correlation coefficients between each of the process parameters in the second groups and the actual measurement values at the measurement points of the workpieces; and
selecting the process parameter in each of the second groups with the largest second correlation coefficient as representative, thereby obtaining a plurality of representative parameters;
determining if the number of the workpieces is smaller than n times of the number of the representative parameters, wherein n is greater than 1, thereby obtaining a second result;
when the second result is yes, performing a parameter-reduction step for selecting a plurality of key parameters from the representative parameters; when the second result is no, considering all of the representative parameters as a plurality of key parameters; and
simplifying the sets of process data as a plurality of sets of critical process data, wherein each of the sets of critical process data consisting of a plurality of key parameters;
performing a parameter-optimization step, the parameter-optimization step comprising:
using the sets of critical process data and their corresponding sets of metrology data to build a predictive model in accordance with an algorithm;
selecting at least one adjusting parameter from the key parameters; determining a parameter count of the adjusting parameters desired to be adjusted;
setting an adjustment amount of each of the adjusting parameters desired to be adjusted;
performing an adjustment step for conjecturing at least one predicted measurement value of the at least one measurement point by inputting values of one set of critical process data to the predictive model and setting at least one value of the at least one adjusting parameter in accordance the parameter count and the adjustment amount;
determining if the at least one predicted measurement value of the at least one measurement point enters an allowable range of a quality target value, thereby obtaining a determination result, wherein, when the determination result is no, the adjustment step is repeated.

12. The computer program product as claimed in claim 11, further to comprising:
performing a data-preprocessing step, the data-preprocessing step comprising:
deleting the process parameters in the sets of process data of which the standard deviations are smaller than a first threshold value;
deleting the process parameters in the first half of sets of process data of which the standard deviations are smaller than the first threshold value;
deleting the process parameters in the second half of sets of process data of which the standard deviations are smaller than the first threshold value;
deleting the process parameters in the sets of process data of which the coefficients of variation are smaller than a second threshold value; or
deleting the process parameters in the sets of process data of which the correlation coefficients with the actual measurement values at the measurement points of the workpieces are smaller than a third threshold value.

13. The computer program product as claimed in claim 11, wherein the first threshold value is 0.0001, the second threshold value is 0.001 and the third threshold value is 0.01.

14. The computer program product as claimed in claim 11, wherein the algorithm is a partial least squares (PLS), a regression-based partial least squares (PLS), a multi-regression (MR) algorithm, a nonlinear regression algorithm, or a logic regression algorithm.

15. The computer program product as claimed in claim 11, wherein the parameter-reduction step further comprises:
repetitively performing a stepwise selection step on the representative parameters until the input and output numbers of the representative parameters to the stepwise selection step are the same, thereby obtaining a plurality of selected parameters;
determining if the number of the workpieces is smaller than n times of the number of the selected parameters, wherein n is greater than 1, thereby obtaining a third result;
when the third result is yes, sorting the selected parameters in descending order by their second correlation coefficients, and selecting the first M sorted number of selected parameters as the key parameters, wherein M is the number of the workpieces divided by n; and
when the third result is no, selecting the selected parameters as the key parameters.

16. The computer program product as claimed in claim 15, wherein n is equal to 2.5.

17. The computer program product as claimed in claim 11, wherein the parameter-reduction step further comprises:
when the first result is no, determining if the number of the workpieces is smaller than n times of the number of the process parameters, wherein n is greater than 1, thereby obtaining a second result;
when the second result is yes, sorting the process parameters in descending order by their second correlation coefficients, and selecting the first M sorted number of process parameters as a plurality of key parameters, wherein M is the number of the workpieces divided by n.

18. The computer program product as claimed in claim 17, wherein n is equal to 2.5.

19. The computer program product as claimed in claim 11, wherein the correlation coefficient threshold is equal to 0.7.

20. The computer program product as claimed in claim 11, wherein the representative-parameter searching step further comprises:
adding the process parameters of which the absolute values of the first correlation coefficients are smaller than the correlation coefficient threshold to the representative parameters.
